(19) United States
(12) Patent Application Publication
(10) Pub. No.: US 2025/0351300 A1
(43) Pub. Date: Nov. 13, 2025

(54) HEAT DISSIPATION MODULE

(71) Applicant: ASUSTeK COMPUTER INC., Taipei City (TW)

(72) Inventors: Ing-Jer Chiou, Taipei City (TW); Sung-Chuan Huang, Taipei City (TW)

(73) Assignee: ASUSTeK COMPUTER INC., Taipei City (TW)

(21) Appl. No.: 18/744,718

(22) Filed: Jun. 17, 2024

(30) Foreign Application Priority Data
May 9, 2024 (TW) 113117127

(51) Int. Cl. H05K 7/20

(52) U.S. Cl. CPC H05K 7/20309; H05K 7/20136; H05K 7/20318

(57) ABSTRACT

A heat dissipation module including a vapor chamber, an insulating tube, a condensing tube, and a wick member is provided. The vapor chamber has a first chamber and a second chamber communicated with each other. The insulating tube has a first channel and a first wick structure. The first channel is communicated with the first chamber, and a cross-sectional area of the first wick structure has a first proportion in a cross-sectional area of the first channel. The condensing tube has a second channel and a second wick structure. The second channel is communicated with the first channel and the second chamber, and a cross-sectional area of the second wick structure has a second proportion greater than the first proportion in a cross-sectional area of the second channel. The wick member is disposed in the second channel and located at a boundary between the condensing tube and the second chamber.

### CROSS-REFERENCE TO RELATED APPLICATION

This application claims the priority benefit of Taiwan application serial no. 113117127, filed on May 9, 2024. The entirety of the above-mentioned patent application is hereby incorporated by reference herein and made a part of this specification.

### BACKGROUND

### Technical Field

The disclosure relates to a heat dissipation technology, and particularly relates to a heat dissipation module.

### Description of Related Art

As computing performance of a central processing unit or a graphics processor in a notebook computer increases, the central processing unit or the graphics processor releases an extremely large amount of heat during operation. In order to quickly dissipate heat, the notebook computer is usually equipped with a fan, a heat pipe, and a vapor chamber to serve as a heat dissipation module.

Specifically, the vapor chamber is thermally coupled to a heat source, and a zone in the vapor chamber that is in contact with or overlaps with the heat source serve as an evaporation zone. When the evaporation zone absorbs heat from the heat source, a liquid working fluid in a cavity of the vapor chamber evaporates into a gaseous working fluid and flows to a relatively low temperature zone outside the evaporation zone. The gaseous working fluid releases heat in the relatively low temperature zone and condenses into the liquid working fluid, and flows back to the evaporation zone through a wick force.

On the other hand, the heat pipe includes an evaporation section and a condensation section, where the evaporation section is welded to the vapor chamber, and the condensation section is disposed corresponding to an air outlet of the fan. When the liquid working fluid in the evaporation section of the heat pipe absorbs heat from the vapor chamber, the liquid working fluid evaporates into the gaseous working fluid and flows to the condensation section. A heat dissipation airflow blown from the air outlet of the fan blows to the condensation section of the heat pipe, and exchanges heat with the gaseous working fluid in the condensation section, causing the gaseous working fluid to release heat and condense into the liquid working fluid, and flow back to the evaporation section through the wick force.

Since the vapor chamber and the heat pipe are not communicated with each other, poor welding quality may cause a decline in the heat conduction efficiency between the vapor chamber and the heat pipe. In addition, under the influence of a structural design of the heat pipe, it is difficult for the gaseous working fluid to flow to a far end of the condensation section, causing heat to be excessively concentrated on a near end of the condensation section (i.e., a zone close to the evaporation section), resulting in poor usage efficiency of the heat pipe. Therefore, common heat dissipation modules composed of fans, heat pipes, and vapor chambers have problems of poor heat dissipation performance.

### SUMMARY

The disclosure is directed to a heat dissipation module adapted to an electronic device. The electronic device has a fan and a heat source, and the heat dissipation module includes a vapor chamber, an insulating tube, a condensing tube, and a wick member. The vapor chamber has a first chamber and a second chamber communicated with the first chamber. The first chamber has an evaporation zone thermally coupled to the heat source. The insulating tube has a first inner wall surface, a first channel surrounded by the first inner wall surface, and a first wick structure distributed on the first inner wall surface, and the first channel is communicated with the first chamber. In a same cross-section of the insulating tube, a cross-sectional area of the first wick structure has a first proportion in a cross-sectional area of the first channel. The condensing tube has a second inner wall surface, a second channel surrounded by the second inner wall surface, and a second wick structure distributed on the first inner wall surface, and the second channel is communicated with the first channel and the second chamber. In a same cross-section of the condensing tube, a cross-sectional area of the second wick structure has a second proportion greater than the first proportion in a cross-sectional area of the second channel. The wick member is disposed in the second channel and located at a boundary between the condensing tube and the second chamber. The first chamber, the second chamber, the insulating tube, and the condensing tube surround a hollow zone. The fan is disposed in the hollow zone, and an air outlet direction of the fan is toward the condensing tube.

Based on the above description, the vapor chamber spreads heat away from the evaporation zone to prevent heat concentration. Specifically, the vapor chamber disperses a part of the heat to the condensing tube through the insulating tube and discharge the same outward from the condensing tube. Therefore, the heat dissipation module is adapted to accelerate a gas-liquid two-phase change process of the working fluid to improve the heat dissipation performance.

### BRIEF DESCRIPTION OF THE DRAWINGS

FIG. 1 is a schematic diagram of a heat dissipation module according to an embodiment of the disclosure.

FIG. 2A is a schematic cross-sectional view of an insulating tube of FIG. 1 in an example.

FIG. 2B is a schematic cross-sectional view of the insulating tube of FIG. 1 in another example.

FIG. 3 is a schematic cross-sectional view of the condensing tube of FIG. 1.

FIG. 4 is a schematic cross-sectional view of a wick member of FIG. 1 in a condensing tube.

### DESCRIPTION OF THE EMBODIMENTS

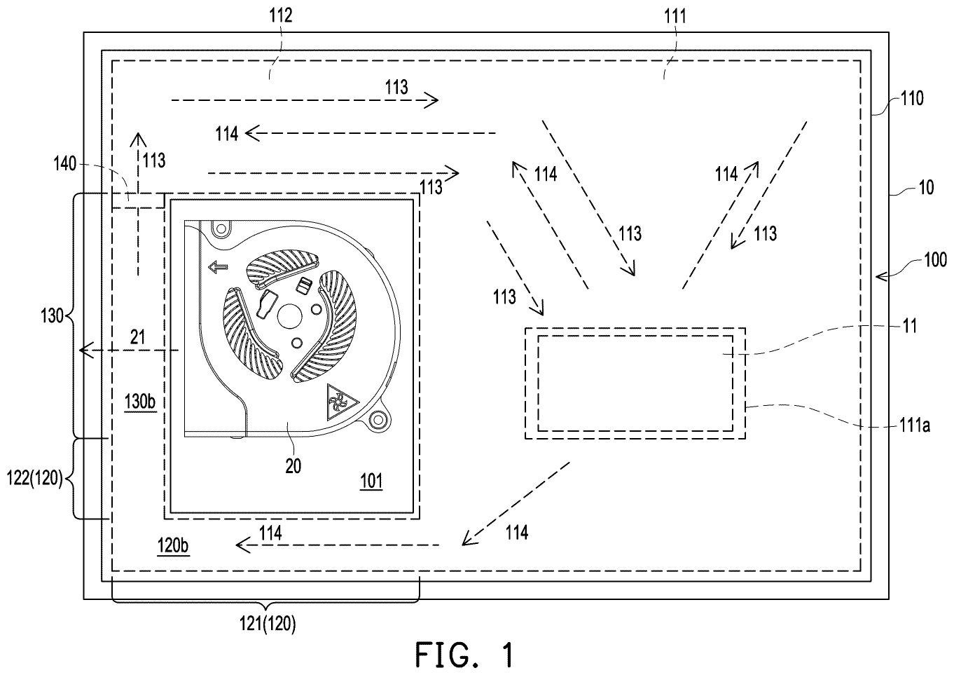

FIG. 1 is a schematic diagram of a heat dissipation module according to an embodiment of the disclosure. Referring to FIG. 1, in the embodiment, a heat dissipation module 100 is disposed in an electronic device 10, and the electronic device 10 has a heat source 11 and a fan 20 inside. For example, the electronic device 10 is a part of a notebook computer (such as a host with logic computing capabilities), but the disclosure is not limited thereto.

In detail, the heat dissipation module 100 includes a vapor chamber 110, an insulating tube 120, a condensing tube 130, and a wick member 140, where the vapor chamber 110 has a first chamber 111 and a second chamber 112 that are communicated with each other, and the first chamber 111 has an evaporation zone 111a thermally coupled to the heat source 11. For example, the heat source 11 is a central processing unit or a graphics processor.

When the evaporation zone 111a absorbs heat from the heat source 11, a liquid working fluid 113 in the first chamber 111 of the vapor chamber 110 evaporates into a gaseous working fluid 114 and flows to a relatively low temperature zone outside the evaporation zone 111a. On the other hand, the gaseous working fluid 114 releases heat in the relatively low temperature zone and condenses into the liquid working fluid 113, and flows back to the evaporation zone 111a through a wick force. For example, the second chamber 112 is the relatively low temperature zone, and the gaseous working fluid 114 may flow from the first chamber 111 to the second chamber 112 and release heat and condense into the liquid working fluid 113 in the second chamber 112, and then flow back to the evaporation zone 111a through the wick force.

As shown in FIG. 1, in the embodiment, two ends of the insulating tube 120 are respectively communicated with the first chamber 111 and the condensing tube 130, and two ends of the condensing tube 130 are respectively communicated with the insulating tube 120 and the second chamber 112. In detail, the second chamber 112 and the insulating tube 120 are connected to a same side of the first chamber 111, and the condensing tube 130 is located between the second chamber 112 and the insulating tube 120. The first chamber 111, the second chamber 112, the insulating tube 120, and the condensing tube 130 surround a hollow zone 101, where the fan 20 is disposed in the hollow zone 101, and the fan 20 blows cold air toward the condensing tube 130 along an air outlet direction 21.

When the liquid working fluid 113 in the first chamber 111 of the vapor chamber 110 evaporates into the gaseous working fluid 114, the gaseous working fluid 114 may flow to the insulating tube 120, and flow to the condensing tube 130 through the insulating tube 120. The gaseous working fluid 114 may release heat and condense into the liquid working fluid 113 in the condensing tube 130. Then, the liquid working fluid 113 flows to the second chamber 112, and then flows back from the second chamber 112 to the evaporation zone 111a of the first chamber 111.

For example, the fan 20 is a centrifugal fan and is surrounded by the first chamber 111, the second chamber 112, the insulating tube 120, and the condensing tube 130. In detail, the fan 20 may blow cold air toward the condensing tube 130 along the air outlet direction 21 to perform heat exchange with the gaseous working fluid 114 in the condensing tube 130, so that the gaseous working fluid 114 releases heat and condenses into the liquid working fluid 113, and flows to the second chamber 112.

As shown in FIG. 1, the condensing tube 130 is perpendicular to at least a part of the insulating tube 120. Furthermore, the insulating tube 120 has a first insulating section 121 connected to the first chamber 111 and a second insulating section 122 connected to the first insulating section 121 and the condensing tube 130, and the second insulating section 122 and the first insulating section 121 have a turning there between. For example, the second insulating section 122 is turned by 90 degrees relative to the first insulating section 121, i.e., the second insulating section 122 is perpendicular to the first insulating section 121. In addition, the condensing tube 130 continuously extends from an end of the second insulating section 122 away from the first insulating section 121 and is perpendicular to the first insulating section 121.

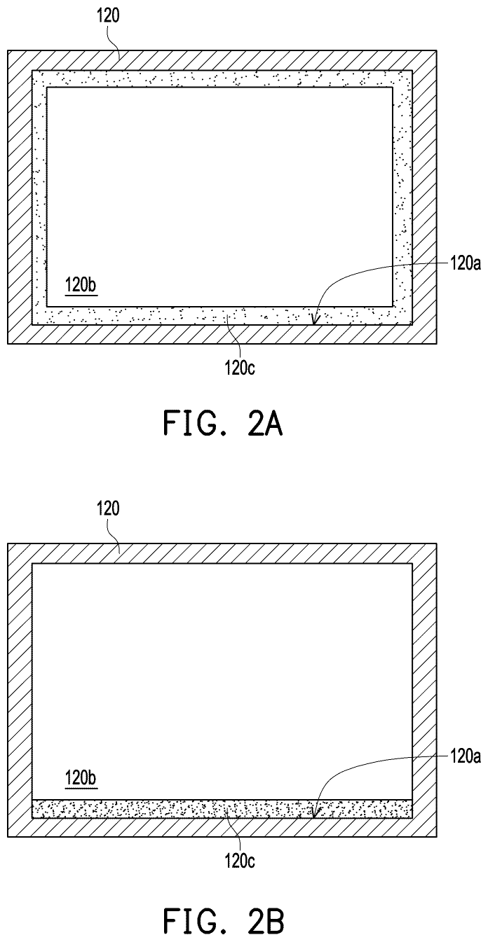

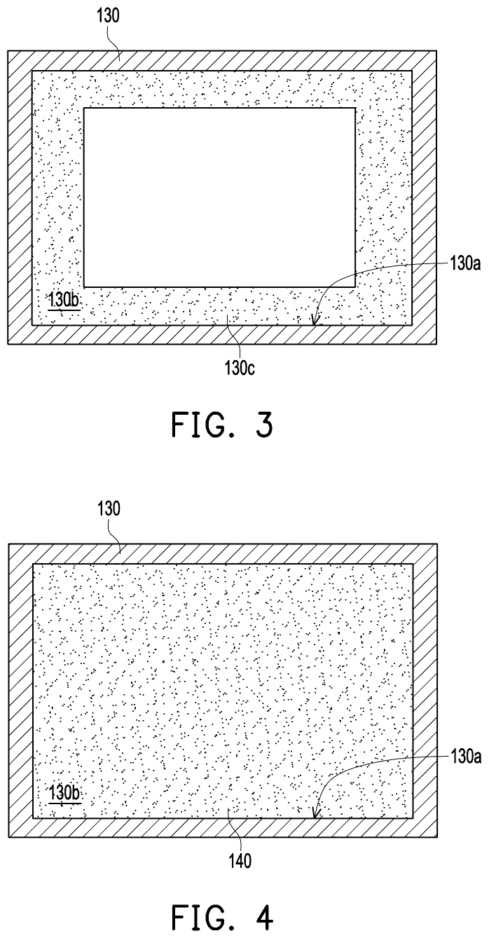

FIG. 2A is a schematic cross-sectional view of the insulating tube of FIG. 1 in an example. FIG. 2B is a schematic cross-sectional view of the insulating tube of FIG. 1 in another example. FIG. 3 is a schematic cross-sectional view of the condensing tube of FIG. 1. FIG. 4 is a schematic cross-sectional view of the wick member of FIG. 1 in the condensing tube. Referring to FIG. 1, FIG. 2A and FIG. 3, in the embodiment, the insulating tube 120 has a first inner wall surface 120a, a first channel 120b surrounded by the first inner wall surface 120a, and a first wick structure 120c distributed on the first inner wall surface 120a, and the first channel 120b is communicated with the first chamber 111. In a same cross-section of the insulating tube 120, the cross-sectional area of the first wick structure 120c has a first proportion in a cross-sectional area of the first channel 120b, for example, less than or equal to 25% or less than or equal to 15%, so as to reduce a flow resistance of the gaseous working fluid 114 in first channel 120b.

The condensing tube 130 has a second inner wall surface 130a, a second channel 130b surrounded by the second inner wall surface 130a, and a second wick structure 130c distributed on the second inner wall surface 130a, and the second channel 130b is communicated with the first channel 120b and second chamber 112. In a same cross-section of the condensing tube 130, a cross-sectional area of the second wick structure 130c has a second proportion greater than the first proportion in a cross-sectional area of the second channel 130b, for example, greater than or equal to 30% and less than or equal to 40%.

Namely, a wick force in the second channel 130b is greater than a wick force in the first channel 120b, so as to reduce an amount of the liquid working fluid 113 flowing back from the condensing tube 130 to the insulating tube 120, and lead the liquid working fluid 113 to the second chamber 112.

As shown in FIG. 2A and FIG. 3, a thickness of the second wick structure 130c is greater than a thickness of the first wick structure 120c. In addition, the first wick structure 120c may cover a top surface, two side surfaces, and a bottom surface relative to the top surface in the first inner wall surface 120a, and the second wick structure 130c may cover a top surface, two side surfaces, and a bottom surface relative to the top surface in the second inner wall surface 130a.

In an example, the first wick structure 120c is configured with equal thickness in the first channel 120b, or in other words, in different cross-sections of the insulating tube 120, the cross-sectional areas of the first wick structure 120c have the same proportion in the cross-sectional areas of the first channel 120b. In another example, the thickness of the first wick structure 120c in the first channel 120b becomes thinner in a direction closer to the second channel 130b, or in other words, in different cross-sections of the insulating tube 120, the cross-sectional areas of the first wick structure 120c have smaller proportions in the cross-sectional areas of the first channel 120b in the direction closer to the second channel 130b.

As shown in FIG. 2B, the first wick structure 120c may only cover the bottom surface of the first inner wall surface 120a, but the disclosure is not limited thereto. The first wick structure 120c may cover any one of the top surface and two side surfaces of the first inner wall surface 120a, or cover at least two of the top surface, two side surfaces, and the bottom surface relative to the top surface of the first inner wall surface 120a.

As shown in FIG. 3 and FIG. 4, the wick member 140 is disposed in the second channel 130b and is located at a boundary between the condensing tube 130 and the second chamber 112. Through the cooperation of the second wick structure 130c and the wick member 140, not only the liquid working fluid 113 is quickly guided from the condensing tube 130 to the second chamber 112, and the liquid working fluid 113 may also be prevented from flowing back from the second chamber 112 to the condensing tube 130.

For example, in the same cross-section of the condensing tube 130, the cross-sectional area of the wick member 140 has a third proportion greater than the second proportion in the cross-sectional area of the second channel 130b, and the third proportion is greater than or equal to 80%, which not only prevents the liquid working fluid 113 from flowing back from the second chamber 112 to the condensing tube 130, but also prevents the gaseous working fluid 114 from flowing into the condensing tube 130 from the second chamber 112, or prevents the gaseous working fluid 114 from flowing into the second chamber 112 from the condensing tube 130. On the other hand, the wick member 140 generates a greater wick force than the second wick structure 130c to accelerate the flow of the liquid working fluid 113 from the condensing tube 130 to the second chamber 112.

In summary, the vapor chamber may spread heat away from the evaporation zone through a gas-liquid two-phase change of the working fluid to prevent heat concentration. Specifically, the vapor chamber may disperse a part of the heat to the condensing tube through the insulating tube, i.e., a part of the gaseous working fluid from the vapor chamber is received by the condensing tube after flowing through the insulating tube. The gaseous working fluid may undergo the gas-liquid two-phase change in the condensing tube to be converted into the liquid working fluid, so that the released heat is discharged outward from the condensing tube. Therefore, the heat dissipation module may accelerate the gas-liquid two-phase change process of the working fluid to improve the heat dissipation performance.

On the other hand, through the cooperation of the second wick structure inside the condensing tube and the wick member located at the boundary between the condensing tube and the second chamber, not only the liquid working fluid is quickly directed from the condensing tube to the second chamber, the liquid working fluid may also be prevented from flowing back from the second chamber to the condensing tube. In addition, through the cooperation of the first wick structure inside the insulating tube and the second wick structure inside the condensing tube, the amount of liquid working fluid flowing back from the condensing tube to the insulating tube is reduced.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A heat dissipation module, adapted to an electronic device, wherein the electronic device has a fan and a heat source, the heat dissipation module comprising:
a vapor chamber, comprising:
a first chamber, having an evaporation zone thermally coupled to the heat source; and
a second chamber, communicated with the first chamber;
an insulating tube, having a first inner wall surface, a first channel surrounded by the first inner wall surface, and a first wick structure distributed on the first inner wall surface, wherein the first channel is communicated with the first chamber, and in a same cross-section of the insulating tube, a cross-sectional area of the first wick structure has a first proportion in a cross-sectional area of the first channel;
a condensing tube, having a second inner wall surface, a second channel surrounded by the second inner wall surface, and a second wick structure distributed on the first inner wall surface, wherein the second channel is communicated with the first channel and the second chamber, in a same cross-section of the condensing tube, a cross-sectional area of the second wick structure has a second proportion in a cross-sectional area of the second channel, and the second proportion is greater than the first proportion; and
a wick member, disposed in the second channel, and located at a boundary between the condensing tube and the second chamber,
wherein the first chamber, the second chamber, the insulating tube, and the condensing tube surround a hollow zone, the fan is disposed in the hollow zone, and an air outlet direction of the fan is toward the condensing tube.

2. The heat dissipation module as claimed in claim 1, wherein the second proportion is greater than or equal to 30%.

3. The heat dissipation module as claimed in claim 2, wherein the first proportion is less than or equal to 25%.

4. The heat dissipation module as claimed in claim 2, wherein the first proportion is less than or equal to 15%.

5. The heat dissipation module as claimed in claim 2, wherein the second proportion is less than or equal to 40%.

6. The heat dissipation module as claimed in claim 1, wherein the second chamber and the insulating tube are connected to a same side of the first chamber, and the condensing tube is located between the second chamber and the insulating tube.

7. The heat dissipation module as claimed in claim 1, wherein the condensing tube is perpendicular to at least a part of the insulating tube.

8. The heat dissipation module as claimed in claim 1, wherein the insulating tube has a first insulating section connected to the first chamber and a second insulating section connected to the first insulating section and the condensing tube, and there is a turning between the second insulating section and the first insulating section.

9. The heat dissipation module as claimed in claim 8, wherein the condensing tube and the second insulating section are perpendicular to the first insulating section.

10. The heat dissipation module as claimed in claim 1, wherein in the same cross-section of the condensing tube, a cross-sectional area of the wick member has a third proportion greater than the second proportion in the cross-sectional area of the second channel, and the third proportion is greater than or equal to 80%.
